(19) United States
(12) Patent Application Publication
(10) Pub. No.: US 2008/0268607 A1
(43) Pub. Date: Oct. 30, 2008

(54) Method of Fabricating Semiconductor Device

(75) Inventor: Guee Hwang Sim, Gangneung-si (KR)

Correspondence Address: MARSHALL, GERSTEIN & BORUN LLP, 233 S. WACKER DRIVE, SUITE 6300, SEARS TOWER, CHICAGO, IL, 60606, US

(73) Assignee: HYNIX SEMICONDUCTOR INC., Icheon-si (KR)

(21) Appl. No.: 11/962,376

(22) Filed: Dec. 21, 2007

(30) Foreign Application Priority Data
Apr. 25, 2007 (KR) 10-2007-040401

(51) Int. Cl. H01L 21/76

(52) U.S. Cl. 438/421; 257/E21.573

(57) ABSTRACT

This patent relates to a method of fabricating a semiconductor device. Gate insulating layer patterns and gate electrode layer patterns may be formed over a semiconductor substrate. A photoresist pattern through which part of a region between the gate electrode layer patterns is exposed may be formed over the semiconductor substrate including the gate electrode layer patterns. A passivation film, having an etch rate slower than that of the semiconductor substrate, may be formed on the photoresist pattern. A first trench may be formed in the semiconductor substrate using an etch process by employing the passivation film and the photoresist pattern as an etch mask. An ion implantation process may be performed on the semiconductor substrate in which the first trench is formed.

This patent claims priority to Korean patent application number 10-2007-40401, filed on Apr. 25, 2007, the disclosure of which is incorporated by reference in its entirety.

### TECHNICAL FIELD

This patent relates to a method of fabricating a semiconductor device and, more particularly, to a method of fabricating a semiconductor device, where a gate electrode film under a photoresist film is protected when forming a trench in a high-voltage region.

### BACKGROUND OF THE INVENTION

In order to perform erase and write operations in non-volatile memory devices such as flash memory devices, a high voltage transistor capable of passing or switching a high voltage is used.

A process of forming a high voltage transistor is as follows. A gate insulating layer and a gate electrode film are formed over a semiconductor substrate. A cell region is patterned using hard mask film patterns for forming patterns and a trench is formed in the cell region. A peripheral region including a high-voltage region is patterned using the hard mask film patterns for performing a patterning process, thus forming a trench in the peripheral region.

A high voltage trench for improving electrical isolation of elements is further formed between high voltage gate patterns formed in the high-voltage region of the peripheral region. In the process of forming the high voltage trench, a photoresist film is formed over the semiconductor substrate in which the gate pattern is formed and is then patterned using exposure and development processes. An etching process is performed along the photoresist pattern and an ion implantation process is then implemented. Corner portions of the high voltage gate pattern may be vulnerable to the etching and ion implantation processes. In particular, the corner portions of the gate electrode may be exposed during the etching process. When the ion implantation process is performed after the etching process, ions may penetrate into the gate electrode through the photoresist pattern.

Ion impurities infiltrated into the high voltage gate electrode layer significantly lower the electrical properties of the semiconductor device. Since the device is intended for high voltage use, the presence of impurities in the semiconductor device reduce its ability to withstand a high junction breakdown voltage when a subsequent high voltage is applied.

### SUMMARY OF THE INVENTION

This patent is directed to a method of fabricating a semiconductor device for preventing damage to a photoresist film and the infiltration of ion impurities when an etching process using the photoresist film is performed in a high-voltage region, by forming a passivation film by performing a silylation process on a surface of a photoresist pattern, and performing the etch process and an ion implantation process.

A method of fabricating a semiconductor device according to an embodiment of the invention includes: forming gate insulating layer patterns and gate electrode layer patterns over a semiconductor substrate, forming a photoresist pattern through which at least a portion of a region between the gate electrode layer patterns is exposed over the semiconductor substrate including the gate electrode layer patterns, forming a passivation film, having an etch rate slower than the semiconductor substrate, on the photoresist pattern, forming a first trench in the semiconductor substrate using an etching process employing the passivation film and the photoresist pattern as an etch mask, and performing an ion implantation process on the semiconductor substrate in which the first trench is formed.

In an embodiment of the invention, a second trench may be further formed by etching the semiconductor substrate between the gate electrode layer patterns.

In an embodiment of the invention, the second trench may have a width wider than the first trench. Further, the second trench may have a depth shallower than the first trench. The gate electrode layer pattern may be formed in a peripheral region of the semiconductor substrate.

In an embodiment of the invention, the gate electrode layer may be formed from a polysilicon layer or a nitride layer. Alternatively, the gate electrode layer may be formed by laminating the polysilicon layer and the nitride layer.

In an embodiment of the invention, the passivation film may be formed by performing a silylation process on a surface of the photoresist film.

In an embodiment of the invention, the silylation process for forming the passivation film may be performed by reacting a reagent containing aminosiloxane (that is, bifunctional oligomeric) to the photoresist film. The reagent may include silicon-based polymer or carbon-based reagent.

In an embodiment of the invention, the passivation film may be formed by modifying part of the photoresist pattern into a SiO₂ film. The SiO₂ film may be formed by changing the photoresist pattern of approximately 50 to 1000 angstrom in thickness.

In an embodiment of the invention, the first trench may have a depth of 500 to 10000 angstrom. The ion implantation process may be performed using a field stop ion implantation process.

### BRIEF DESCRIPTION OF THE DRAWINGS

For a more complete understanding of the disclosure, reference should be made to the following detailed description and accompanying drawings wherein:

FIGS. 1A to 1F are sectional views illustrating a method of fabricating a semiconductor device according to an embodiment of the invention.

### DETAILED DESCRIPTION

This patent is not limited to the disclosed embodiments, but may be implemented in various manners. The embodiments are provided to complete the disclosure of the patent and to allow those having ordinary skill in the art to understand the scope of the patent. The present invention is defined by the appended claims.

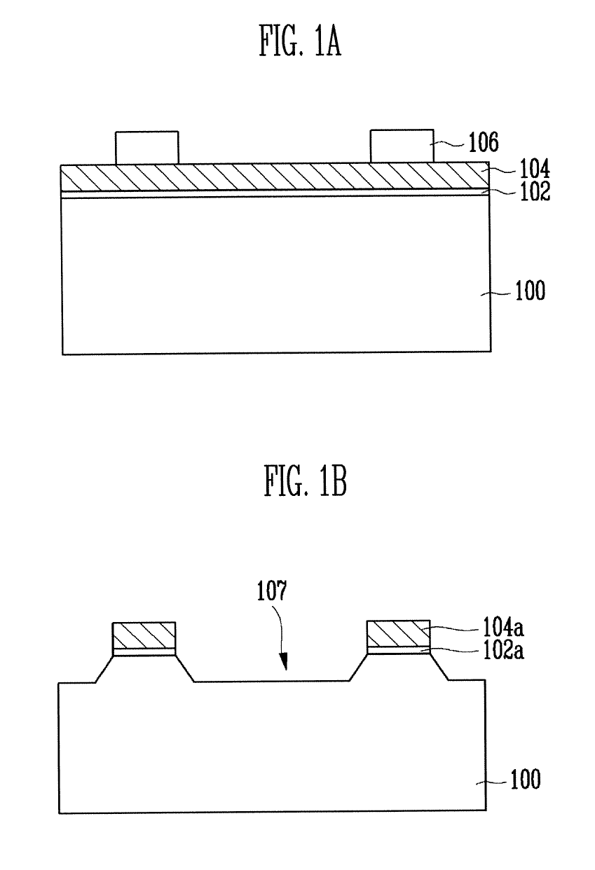

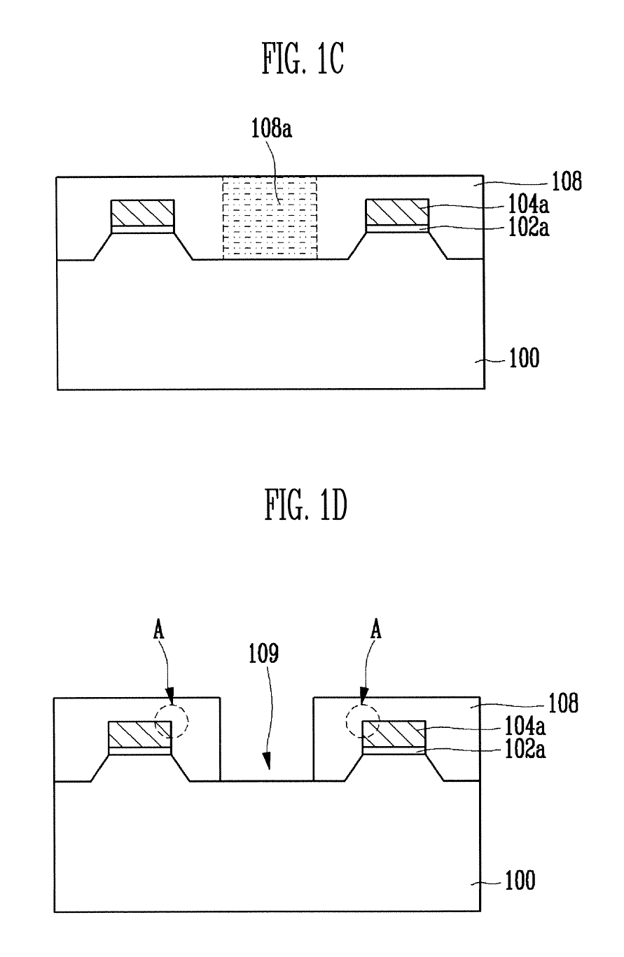

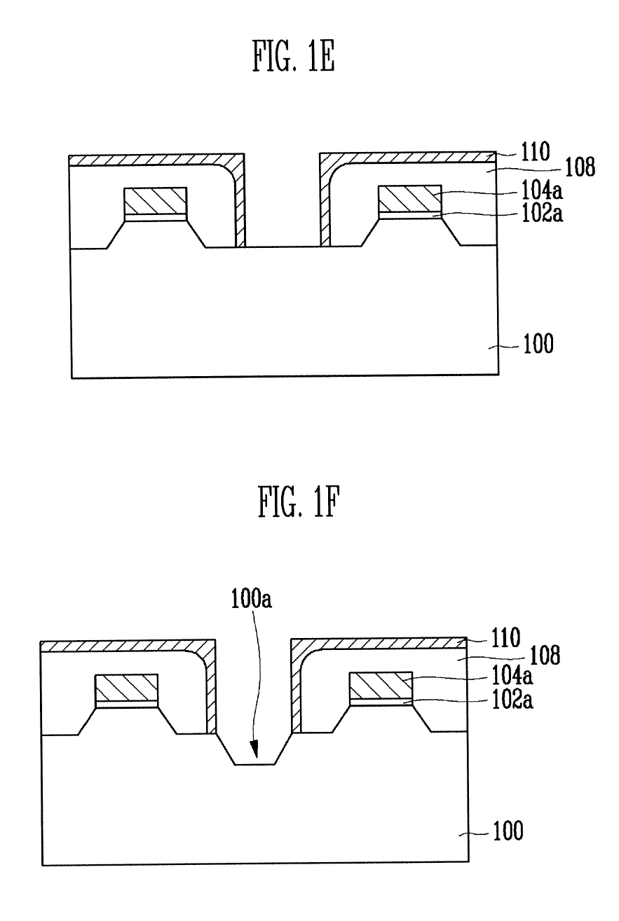

FIG. 1A is a sectional view illustrating a high-voltage region of a semiconductor substrate 100. A gate insulating layer 102, a gate electrode film 104, and hard mask film patterns 106 are formed over the semiconductor substrate 100. The gate insulating layer 102 may be formed, for example, from an oxide film. The gate electrode film 104 may be formed, for example, by laminating a polysilicon layer and a nitride layer. Alternatively, the gate electrode film 104 may be formed using any one of the polysilicon layer or the nitride layer. The hard mask film patterns 106 may be used to form high voltage gates.

Referring to FIG. 1B, a peripheral region of the semiconductor substrate 100 is illustrated. An etching process may be performed along the hard mask film patterns 106 (as shown FIG. 1A), thus forming gate electrode layer patterns 104a and gate insulating layer patterns 102a. At least a portion of the semiconductor substrate 100 may be removed during the etching process to form a trench 107. Once the trench etching is completed, the hard mask film patterns 106 are removed by any known techniques. In an embodiment, the peripheral region may be patterned after the patterns 102a, 104a and the trench 107 are formed in a cell region (not shown). Alternatively, the patterns 102a, 104a and the trench 107 may be formed in the cell region after the patterns 102a, 104a and the trench 107 are formed in the peripheral region.

FIGS. 1C-1F are sectional views illustrating a method of forming a high voltage trench 100a (as depicted in FIG. 1F). A photoresist film 108 may be formed over the semiconductor substrate 100 having the gate electrode layer patterns 104a formed thereon such that the entire gate electrode layer patterns 104a is covered by the photoresist film 108. The photoresist film 108 may be formed, for example, from a photosensitive material not containing silicon, for example, using a spin coating method.

An exposure process may be performed to define an exposure region 108a. In an embodiment, a positive exposure process may be performed for removing the exposure region by allowing polymer bond chains of the photoresist film 108 to be broken through exposure. Alternatively, a negative exposure process may be performed for removing regions other than the exposure region by allowing the polymer bond chains of the photoresist film 108 to be strengthened through exposure. As shown in FIG. 1C, the positive exposure process is described as an example.

Referring to FIG. 1D, a development process for removing the exposure region 108a (as shown in FIG. 1C) of the photoresist film 108 may be implemented, thus forming a hole 109, for example, through a central region of the trench 107 (as shown FIG. 1B). The development process may be performed, for example, using a wet development process. Other types of technique may be used.

Etching and ion implantation processes may be performed along the patterned photoresist film 108 and the gate electrode layer patterns 104a may be influenced during the processes. As mentioned in FIG. 1C, when the photoresist 108 is formed by performing the spin coating method, a thickness of the photoresist film 108 at the corner portions A of the gate electrode layer patterns 104a may become thin. The corner portions A of the gate electrode layer patterns 104a may be vulnerable to the etching and ion implantation processes. To prevent infiltration of impurities during the processes, a passivation film 110 (as shown in FIG. 1E) may be formed on a surface of the photoresist film 108.

Referring to FIG. 1E, a silylation process for forming a passivation film 110 may be performed on the surface of the photoresist film 108. The silylation process may be performed by reacting a reagent, for example, silicon-based polymer or carbon-based reagent), containing aminosiloxane (that is, bifunctional oligomeric), to the photoresist film 108. The passivation film 110 may be, for example, a cross-linked SiO₂ film. The passivation film 110 may be formed thickly diffused at the corner portions of the patterned photoresist film 108 during the silylation process while changing the photoresist film 108 of approximately 50 to 1000 angstrom in thickness. This may advantageously function to protect the gate electrode layer patterns 104a when etching and ion implantation processes are performed. Further, a trench of a micro pattern may be formed easily to prevent any loss of the photoresist film 108.

Referring to FIG. 1F, at least a portion of the exposed semiconductor substrate 100 may be removed by performing an etching process along the pattern of the photoresist film 108 on which the passivation film 110 is formed, thus forming a high voltage trench 100a. As shown, the high voltage trench 100a may be deeper than the trench 107 (as depicted in FIG. 1B) to electrically insulate high voltage elements formed in the semiconductor substrate 100. During the etching process, the passivation film 110 may be partially etched so that the thickness of the passivation film 110 may become thin. Since the pattern of the photoresist film 108 is protected by the passivation film 110, the etch rate of the photoresist film 108 may be slowed. The high voltage trench 100a may have a depth of approximately 500 to 10000 angstrom. Accordingly, distance margin between surfaces of the photoresist film 108 remaining from the corners of the gate electrode layer patterns 104a may be secured.

Once the high voltage trench 100a is formed, a field stop ion implantation process may be performed along the pattern of the photoresist film 108 where the passivation film 110 remains, to electrically insulate high voltage elements. The field stop ion implantation process may be performed, for example, by implanting a P type impurity. Further, when the ion implantation process is implemented, the passivation film 110 formed on the gate electrode layer patterns 104a may prevent the impurity from infiltrating into the gate electrode layer patterns 104a. By preventing the infiltration of the impurity, a gate electrode may be able to withstand the breakdown voltage of an electrically high voltage junction.

According to the invention, when an etching process is performed on the high-voltage region, a silylation process may be performed on the surface of the photoresist pattern in order to form the passivation film. Accordingly, loss of the photoresist film due to the etching process may be reduced and a thickness of the photoresist film may be reduced. In doing so, the gate electrode layer may be protected from the etching process. The infiltration of an impurity into the gate electrode in a subsequent ion implantation process may be prevented and, therefore, the gate electrode may be able withstand the breakdown voltage of a high voltage junction. Further, a trench formation process may be performed between the trench and the semiconductor substrate in the peripheral region, before the photoresist film is formed. Accordingly, malfunction of a semiconductor device may be prevented.

What is claimed is:

1. A method of fabricating a semiconductor device, comprising:
forming gate layer patterns over a semiconductor substrate;
forming a photoresist pattern over the semiconductor substrate including the gate layer patterns;
forming a passivation film on the photoresist pattern, the passivation film having an etch rate slower than the semiconductor substrate;
forming a first trench in the semiconductor substrate using an etch process employing the passivation film and the photoresist pattern as an etch mask; and
performing an ion implantation process in the first trench.

2. The method of claim 1, wherein the gate layer patterns comprise gate insulating layer patters and gate electrode layer patterns.

3. The method of claim 2, wherein the gate electrode layer patterns are formed in a peripheral region of the semiconductor substrate.

4. The method of claim 3, wherein the gate electrode layer patterns are selected from the group consisting of a polysilicon, a nitride, and combinations thereof.

5. The method of claim 3, further comprising:
forming a second trench by etching at least a portion of the semiconductor substrate between the gate electrode layer patterns;
gap-filling the second trench including covering the entire gate electrode layer patterns, using a photoresist film;
forming a region within the photoresist film; and
forming the passivation film on a surface of the photoresist film.

6. The method of claim 4, wherein the passivation film is formed by performing a silvlation process.

7. The method of claim 5, wherein the passivation film is formed by modifying a portion of the photoresist pattern into a SiO₂ film.

8. The method of claim 7, wherein the SiO₂ film is formed by changing the photoresist pattern of approximately 50 to 1000 angstrom in thickness.

9. The method of claim 1, wherein the first trench has a depth of 500 to 10000 angstrom.

10. The method of claim 1, wherein the ion implantation process is performed using a field stop ion implantation process.

11. The method of claim 5, wherein the second trench has a width wider than the first trench.

12. The method of claim 11, wherein the second trench has a depth shallower than the first trench.

13. The method of claim 11, wherein the first trench has a depth of approximately 500 to 10000 angstrom.

14. A method of fabricating a semiconductor device, comprising:
forming gate insulating layer patterns and gate electrode layer patterns over a semiconductor substrate;
forming a photoresist pattern over the semiconductor substrate including the gate electrode layer patterns;
forming a passivation film, having an etch rate slower than that of the semiconductor substrate, on the photoresist pattern;
forming a first trench in the semiconductor substrate using an etch process employing the passivation film and the photoresist pattern as an etch mask; and
performing an ion implantation process on the semiconductor substrate in which the first trench is formed.

15. The method of claim 14, further comprising forming a second trench by etching the semiconductor substrate between the gate electrode layer patterns before forming the photoresist pattern, wherein the first trench has a width wider than the second trench and further the first trench has a depth shallower than the second trench.

16. The method of claim 14, wherein the gate electrode layer patterns is selected from a group consisting of a polysilicon layer, a nitride layer, and combination of the polysilicon layer and the nitride layer.

17. The method of claim 14, wherein the passivation film is formed by performing a silylation process on a surface of the photoresist film, the silylation process is performed by reacting a reagent containing aminosiloxane, including bifunctional oligomeric, to the photoresist film.

18. The method of claim 17, wherein the reagent is silicon-based polymer or carbon-based reagent.

19. The method of claim 17, wherein the passivation film is formed by modifying part of the photoresist pattern into a SiO₂ film, the SiO₂ film is formed by changing the photoresist pattern of approximately 50 to 1000 angstrom in thickness.

20. The method of claim 15, wherein the second trench has a depth of approximately 500 to 10000 angstrom.

21. The method of claim 14, wherein the ion implantation process is performed using a field stop ion implantation process.
